(19) United States
(12) Patent Application Publication
(10) Pub. No.: US 2024/0204051 A1
(43) Pub. Date: Jun. 20, 2024

(54) SILICON CARBIDE SEMICONDUCTOR SUBSTRATE, METHOD OF MANUFACTURING SILICON CARBIDE SEMICONDUCTOR SUBSTRATE, SILICON CARBIDE SEMICONDUCTOR DEVICE, AND METHOD OF MANUFACTURING SILICON CARBIDE SEMICONDUCTOR DEVICE

(71) Applicant: FUJI ELECTRIC CO., LTD., Kawasaki-shi (JP)

(72) Inventors: Kensuke TAKENAKA, Tsukuba-city (JP); Takeshi TAWARA, Tsukuba-city (JP); Shinsuke HARADA, Tsukuba-city (JP)

(73) Assignee: FUJI ELECTRIC CO., LTD., Kawasaki-shi (JP)

(21) Appl. No.: 18/497,450

(22) Filed: Oct. 30, 2023

(30) Foreign Application Priority Data
Dec. 15, 2022 (JP) 2022-200640

(51) Int. Cl. H01L 29/06; H01L 21/04; H01L 21/66; H01L 29/10; H01L 29/16; H01L 29/66; H01L 29/78

(52) U.S. Cl. CPC H01L 29/063; H01L 21/046; H01L 22/14; H01L 29/1095; H01L 29/1608; H01L 29/66068; H01L 29/7813

(57) ABSTRACT

A silicon carbide semiconductor substrate has a silicon carbide semiconductor substrate of a first conductivity type and a first semiconductor layer of the first conductivity type, provided at a front surface of the silicon carbide semiconductor substrate and having a doping concentration lower than that of the silicon carbide semiconductor substrate. A portion of the first semiconductor layer contains a dopant of a second conductivity type. A concentration of the dopant of the second conductivity type in the first semiconductor layer differs in a direction parallel to an orientation flat or in a direction orthogonal to the orientation flat, the orientation flat indicating a crystal axis direction, such that a distribution of a net doping concentration in the first semiconductor layer has a variation equal to or less than a predetermined threshold.

### TECHNICAL FIELD

Embodiments of the invention relate to a silicon carbide semiconductor substrate, a method of manufacturing a silicon carbide semiconductor substrate, a silicon carbide semiconductor device, and a method of manufacturing a silicon carbide semiconductor device.

### BACKGROUND ART

Single crystal silicon (Si) is conventionally used as a material of power semiconductor devices that control high voltages and large currents. Silicon power semiconductor devices include various types that are selectively used according to purpose. For example, PiN diodes (P-intrinsic-N diodes), bipolar transistors, and insulated gate bipolar transistors (IGBTs) are so-called bipolar devices. While these devices have a high current density, high-speed switching is not possible and, for example, the frequency usage limit is several kHz for bipolar transistors and about 20 KHz for IGBTs. On the other hand, while power metal oxide semiconductor field effect transistors (MOSFETs) can be used at high speeds up to several MHz, MOSFETs cannot handle large currents. Nonetheless, there is a strong demand in the market for large-current, high-speed power semiconductor devices and thus, IGBTs and power MOSFETs have been intensively developed and improved, and the performance of power devices has nearly reached the theoretical limit determined by the silicon material.

Further, other materials for power semiconductor devices have been investigated and silicon carbide (SiC) has recently attracted particular attention for next-generation power semiconductor devices excelling in terms of having low ON voltage, high-speed characteristics, and high-temperature characteristics. The reason why is that SiC is an extremely stable material chemically, has a wide band gap of 3.26 eV in an instance of 4H-SiC, may be used very stably as a semiconductor even at high temperatures, and further has a critical field strength that is at least one order of magnitude greater than that of silicon. SiC has a good possibility of exceeding the material limits of silicon and therefore, future growth in power semiconductor applications is expected to be significant.

As for silicon carbide semiconductor devices, Schottky barrier diodes (SBDs), planar gate structure and trench gate structure vertical metal oxide semiconductor field effect transistors (MOSFETs) have been commercialized.

In such silicon carbide semiconductor devices, an n⁻-type silicon carbide epitaxial layer is deposited on a front surface of an n⁺-type silicon carbide substrate as a drift layer. For example, on the n⁺-type silicon carbide substrate doped with nitrogen (N) of about 5×10¹⁸/cm³, an n⁻-type silicon carbide epitaxial layer having a dopant concentration of 1×10¹⁶/cm³ and thickness of about 10 μm is deposited using a thermal CVD apparatus. In the n⁻-type silicon carbide epitaxial layer, at a first surface thereof opposite to a second surface thereof facing the n⁺-type silicon carbide substrate, a surface structure of silicon carbide semiconductor device such as a MOS structure is formed.

Further, a technique has been proposed in which a distribution of the film thickness of a semiconductor epitaxial layer of a first conductivity type and a distribution of dopant concentration of the semiconductor epitaxial layer have a positive correlation, whereby variation of device characteristics in a plane parallel to a main surface of a semiconductor wafer is suppressed (for example, refer to Patent Document 1).

### PRIOR ART LITERATURE

### Patent Literature

Patent Document 1: Japanese Laid-Open Patent Publication No. 2020-155687

### DISCLOSURE OF INVENTION

### Problem to be Solved by the Invention

The distribution of the film thickness of a conventional n⁻-type silicon carbide epitaxial layer is normally 5% or less, but the distribution of the doping concentration is about 10% or less, which is worse than the distribution of the film thickness. Here, FIG. 14 is a top view depicting the conventional silicon carbide semiconductor substrate. FIG. 15 is a graph showing the distribution of the dopant along an x-axis direction of the conventional silicon carbide semiconductor substrate. FIG. 16 is a graph showing the distribution of the dopant along a y-axis direction of the conventional silicon carbide semiconductor substrate.

In FIG. 14, a direction parallel to an orientation flat (OF) indicating the crystal axis direction is the x-axis while a direction orthogonal to the OF is a y-axis. In FIGS. 15 and 16, the horizontal axis indicates the amount of movement from a center of the n⁺-type silicon carbide substrate in units of mm. The vertical axis indicates the doping concentration in units of/cm³.

As depicted in FIG. 15, in the x-axis direction, while the distribution of the dopant is substantially constant, as depicted in FIG. 16, in the y-axis direction, the distribution of the dopant increases with increasing distance from the center and greatly varies depending on the distance. As described, in the n⁻-type silicon carbide epitaxial layer, depending on the temperature distribution and/or distribution of gas in the epitaxial growth furnace, the distribution of the dopant may vary in one direction.

This is due to factors such as the dopant gas concentration and wafer temperature as well as complex factors that change the dopant take-up efficiency depending on the ratio of C elements and Si elements (C/Si ratio) close to the growth surface. When a surface structure is formed on the n⁻-type silicon carbide epitaxial layer with such distribution of doping concentration, a problem arises in that variation of the breakdown voltage and on-resistance of the silicon carbide semiconductor device is exacerbated.

To solve the problems associated with the conventional techniques, one object of the present invention is to provide a silicon carbide semiconductor substrate, a method of manufacturing a silicon carbide semiconductor substrate, a silicon carbide semiconductor device, and a method of manufacturing a silicon carbide semiconductor device that suppress variation of the distribution of the net carrier concentration of the n⁻-type silicon carbide epitaxial layer.

### Means for Solving Problem

To solve the problems described above and achieve an object of the present invention, a silicon carbide semiconductor substrate according to the present invention has the following features. The silicon carbide semiconductor substrate has a silicon carbide semiconductor substrate of a first conductivity type and a first semiconductor layer of the first conductivity type, provided at a front surface of the silicon carbide semiconductor substrate, the first semiconductor layer having a doping concentration lower than that of the silicon carbide semiconductor substrate. A portion of the first semiconductor layer contains a dopant of a second conductivity type and the dopant of the second conductivity type has a difference in concentration in a direction parallel or orthogonal to an orientation flat that indicates a crystal axis direction.

To solve the problems described above and achieve an object of the present invention, a method of manufacturing a silicon carbide semiconductor substrate according to the present invention has the following features. First, a first process is performed in which, at a front surface of a silicon carbide semiconductor substrate of a first conductivity type, a first semiconductor layer of the first conductivity type is formed, the first semiconductor layer having a doping concentration lower than that of the silicon carbide semiconductor substrate. Next, a second process is performed in which distribution of the doping concentration of the first semiconductor layer is measured. Next, a third process is performed in which a dopant of a second conductivity type is implanted in the first semiconductor layer. In the third process, an amount of the dopant of the second conductivity type is reduced for a region of the first semiconductor layer where the doping concentration is relatively low, and the amount of dopant of the second conductivity type is increased for a region of the first semiconductor layer where the doping concentration is relatively high.

Further, the method of manufacturing the silicon carbide semiconductor substrate according to the present invention is characterized in that, in the invention described above, in the third process, the dopant of the second conductivity type is implanted in a predetermined region from an interface between the silicon carbide semiconductor substrate and the first semiconductor layer.

Further, the method of manufacturing the silicon carbide semiconductor substrate according to the present invention is characterized in that, in the invention described above, in the third process, the dopant of the second conductivity type is implanted in a predetermined region of the first semiconductor layer, from a surface thereof opposite that facing the silicon carbide semiconductor substrate.

To solve the problems described above and achieve an object of the present invention, a silicon carbide semiconductor device according to the present invention has the following features. At a front surface of a silicon carbide semiconductor substrate of a first conductivity type, a first semiconductor layer of the first conductivity type is provided, the first semiconductor layer having a doping concentration lower than that of the silicon carbide semiconductor substrate. At a surface of the first semiconductor layer, opposite to a surface thereof facing the silicon carbide semiconductor substrate, a second semiconductor layer of a second conductivity type is provided. At the surface of the second semiconductor layer, first semiconductor regions of the first conductivity type are selectively provided. Trenches penetrating through the second semiconductor layer and the first semiconductor regions and reaching the first semiconductor layer are provided. In the trenches, gate electrodes are provided via gate insulating films. A first electrode in contact with the first semiconductor regions and the second semiconductor layer is provided. At a back surface of the silicon carbide semiconductor substrate, a second electrode is provided. A portion of the first semiconductor layer contains a dopant of the second conductivity type, the dopant of the second conductivity type having a difference in concentration in a direction parallel to or orthogonal to a crystal axis direction indicted by an orientation flat.

To solve the problems described above and achieve an object of the present invention, a method of manufacturing a silicon carbide semiconductor device according to the present invention has the following features. First, a first process is performed in which, at a front surface of a silicon carbide semiconductor substrate of a first conductivity type, a first semiconductor layer of the first conductivity type is formed, the first semiconductor layer having a doping concentration lower than that of the silicon carbide semiconductor substrate. Next, a second process is performed in which a distribution of the doping concentration of the first semiconductor layer is measured. Next, a third process is performed in which a dopant of a second conductivity type is implanted in the first semiconductor layer. Next, a fourth process is performed in which, at a surface of the first semiconductor layer, opposite a surface thereof facing the silicon carbide semiconductor substrate, a second semiconductor layer of the second conductivity type is formed. Next, a fifth process is performed in which, at the surface of the second semiconductor layer, first semiconductor regions of the first conductivity type are selectively formed. Next, a sixth process is performed in which trenches penetrating through the second semiconductor layer and the first semiconductor regions and reaching the first semiconductor layer are formed. Next, a seventh process is performed in which, in the trenches, gate electrodes are formed via gate insulating films. Next, an eighth process is performed in which a first electrode in contact with the first semiconductor regions and the second semiconductor layer is formed. Next, a ninth process is performed which, at a back surface of the silicon carbide semiconductor substrate, a second electrode is formed. In the third process, in a region of the first semiconductor layer where the doping concentration is low, an amount of the dopant of the second conductivity type is reduced and in a region of the first semiconductor layer where the doping concentration is high, the amount of dopant of the second conductivity type is increased.

According to the invention described above, in the first semiconductor layer of the first conductivity type, for a region thereof where the doping concentration is low, the dose is reduced and in the first semiconductor layer of the first conductivity type, for a region thereof where the doping concentration is high, the dose is increased, counter-doping is performed by p-type ion implantation, and thus the distribution of the net carrier concentration of the first semiconductor layer is improved. As a result, variation of the breakdown voltage and variation of the on-resistance of the MOSFET may be improved. Further, hole injection to the drift layer is suppressed by defects generated by ion implantation, whereby expansion of stacking faults may be suppressed even when a body diode conducts.

### Effect of the Invention

The silicon carbide semiconductor substrate, the method of manufacturing the silicon carbide semiconductor substrate, the silicon carbide semiconductor device, and the method of manufacturing the silicon carbide semiconductor device achieve an effect in that variation of the distribution of the net carrier concentration of the n⁻-type silicon carbide epitaxial layer may be suppressed to be 5% or less.

### BRIEF DESCRIPTION OF THE DRAWINGS

FIG. 1 is a cross-sectional view depicting a structure of a silicon carbide semiconductor substrate according to an embodiment.

FIG. 2 is a cross-sectional view of a state of the silicon carbide semiconductor substrate according to the embodiment during manufacture.

FIG. 3 is a cross-sectional view of a state of the silicon carbide semiconductor substrate according to the embodiment during manufacture.

FIG. 4 is a top view depicting an ion implantation method of the silicon carbide semiconductor substrate according to the embodiment.

FIG. 5 is a cross-sectional view of another structure of the silicon carbide semiconductor substrate according to the embodiment.

FIG. 6 is a cross-sectional view of another structure of the silicon carbide semiconductor substrate according to the embodiment.

FIG. 7 is cross-sectional view depicting a structure of a silicon carbide semiconductor device according to the embodiment.

FIG. 8 is a cross-sectional view schematically depicting a state of the silicon carbide semiconductor device according to the embodiment during manufacture.

FIG. 9 is a cross-sectional view schematically depicting a state of the silicon carbide semiconductor device according to the embodiment during manufacture.

FIG. 10 is a cross-sectional view schematically depicting a state of the silicon carbide semiconductor device according to the embodiment during manufacture.

FIG. 11 is a cross-sectional view schematically depicting a state of the silicon carbide semiconductor device according to the embodiment during manufacture.

FIG. 12 is a cross-sectional view schematically depicting a state of the silicon carbide semiconductor device according to the embodiment during manufacture.

FIG. 13 is a cross-sectional view schematically depicting a state of the silicon carbide semiconductor device according to the embodiment during manufacture.

FIG. 14 is a top view depicting a conventional silicon carbide semiconductor substrate.

FIG. 15 is a graph showing distribution of a dopant along an x-axis direction of the conventional silicon carbide semiconductor substrate.

FIG. 16 is a graph showing the distribution of the dopant along a y-axis direction of the conventional silicon carbide semiconductor substrate.

### BEST MODE (S) FOR CARRYING OUT THE INVENTION

Embodiments of a silicon carbide semiconductor device and a method of manufacturing a silicon carbide semiconductor device according to the present invention are described in detail with reference to the accompanying drawings. In the present description and accompanying drawings, layers and regions prefixed with n or p mean that majority carriers are electrons or holes. Additionally, + or − appended to n or p means that the doping concentration is higher or lower, respectively, than layers and regions without + or −. Cases where symbols such as n's and p's that include + or − are the same indicate that concentrations are close and therefore, the concentrations are not necessarily equal. In the description of the embodiments below and the accompanying drawings, main portions that are identical are given the same reference numerals and will not be repeatedly described. Further, with consideration of variation in manufacturing, description indicating the same or equal may be within 5%.

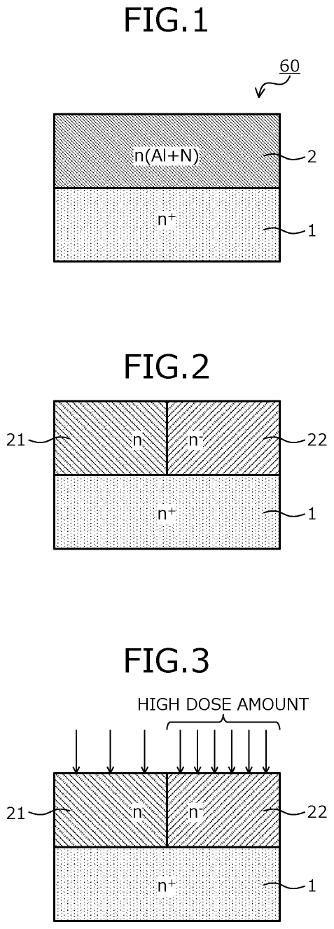

FIG. 1 is a cross-sectional view depicting a structure of a silicon carbide semiconductor substrate according to an embodiment. In a silicon carbide semiconductor substrate 60, on a front surface of an n⁺-type silicon carbide substrate (semiconductor substrate of a first conductivity type) 1 thereof, as a drift layer, an n⁻-type silicon carbide epitaxial layer (first semiconductor layer of the first conductivity type) 2 is deposited. For example, on the n⁺-type silicon carbide substrate 1 doped with N (nitrogen) of about 5×10¹⁸/cm³, the n⁻-type silicon carbide epitaxial layer 2 with a dopant concentration of 1×10¹⁶/cm³ and a thickness of about 10 μm is deposited using a thermal CVD apparatus.

In the n⁻-type silicon carbide epitaxial layer 2, as described in detail hereinafter, variation of the distribution of the net carrier concentration is compensated and improved by ion-implantation of a p-type dopant, which is of the opposite conductivity type. Thus, a portion or all of the n⁻-type silicon carbide epitaxial layer 2 contains a p-type dopant. In the x-axis direction (direction parallel to the OF, refer to FIG. 14) or in the y-axis direction (direction orthogonal to the OF, refer to FIG. 14) of the n⁻-type silicon carbide epitaxial layer 2, there is variation in the distribution of the dopant and this variation is compensated by counter-doping a p-type dopant and improving the distribution of the net carrier concentration, whereby in the x-axis direction or the y-axis direction of the n⁻-type silicon carbide epitaxial layer 2, the p-type doping concentration changes, whereby a difference in the doping concentration arises (doping concentration difference). Doping concentration difference is when the distribution of a dopant concentration of the opposite conductivity type is 10% or higher in the x-axis direction or in the y-axis direction. For example, in an instance in which N is doped in the n⁻-type silicon carbide epitaxial layer 2, Al is implanted in a portion thereof and the Al concentration changes in the x-axis direction or in the y-axis direction of the n⁻-type silicon carbide epitaxial layer 2, creating a doping concentration difference.

In the modification example described above, formation may be such that the n⁻-type silicon carbide epitaxial layer 2 is doped with a p-type dopant, for example, Al, and an n-type dopant, for example, N is ion-implanted to cause inversion to an n-type. In this instance, the entire n⁻-type silicon carbide epitaxial layer 2 contains an n-type dopant and the n-type doping concentration changes in the x-axis direction or in the y-axis direction of the n⁻-type silicon carbide epitaxial layer 2.

As described, variation of the distribution of the net carrier concentration in both directions (the x-axis direction and the y-axis direction) is suppressed and improved in the n⁻-type silicon carbide epitaxial layer 2. As a result, when a MOSFET is fabricated using the silicon carbide semiconductor substrate 60, variation of the breakdown voltage and variation of the on-resistance of the MOSFET may be improved. Further, hole injection to the drift layer is suppressed by defects generated by ion-implantation, whereby expansion of stacking faults may be suppressed even when a body diode conducts.

Next, a method of manufacturing the silicon carbide semiconductor substrate according to the embodiment is described. FIGS. 2 and 3 are cross-sectional views of states of the silicon carbide semiconductor substrate according to the embodiment during manufacture.

First, as depicted in FIG. 2, the n⁺-type silicon carbide substrate 1 containing an n-type silicon carbide is prepared. Subsequently, on a first main surface of the n⁺-type silicon carbide substrate 1, the n⁻-type silicon carbide epitaxial layer 2 containing silicon carbide is epitaxially grown while an n-type dopant, for example, nitrogen atoms, is doped. In the n⁻-type silicon carbide epitaxial layer 2 formed here, there is variation in the doping concentration and the n⁻-type silicon carbide epitaxial layer 2 is configured by an n⁻-type silicon carbide epitaxial layer low-concentration region 21 having a relatively low doping concentration and an n⁻-type silicon carbide epitaxial layer high-concentration region 22 having a relatively high doping concentration. The state up to here is depicted in FIG. 2.

Next, the distribution of doping concentration of the n⁻-type silicon carbide epitaxial layer 2 doped with N is obtained by capacitance voltage (CV) measurement. As a result, positions of the n⁻-type silicon carbide epitaxial layer low-concentration region 21 and the n⁻-type silicon carbide epitaxial layer high-concentration region 22 may be identified.

Next, a p-type dopant is ion-implanted in the n⁻-type silicon carbide epitaxial layer 2. At the wafer surface, a dose (dopant implantation amount) is changed to thereby improve the distribution of the net carrier concentration of the n⁻-type silicon carbide epitaxial layer 2. For example, in the n⁻-type silicon carbide epitaxial layer low-concentration region 21, the dose is lowered while in the n⁻-type silicon carbide epitaxial layer high-concentration region 22, the dose is increased, whereby the distribution of the net carrier concentration of the n⁻-type silicon carbide epitaxial layer 2 may be improved. The state up to here is depicted in FIG. 3.

As described, in the method of manufacturing the silicon carbide semiconductor substrate according to the embodiment, the p-type ion implantation dose is set low with respect to a region of a low doping concentration in the n⁻-type silicon carbide epitaxial layer 2 while the p-type ion implantation dose is set high with respect to a region of a high doping concentration in the n⁻-type silicon carbide epitaxial layer 2, whereby the distribution of the net carrier concentration of the n⁻-type silicon carbide epitaxial layer 2 may be improved.

Further, an n-type ion implantation dose is set high with respect to a region of a low doping concentration in the n⁻-type silicon carbide epitaxial layer 2 and the n-type ion implantation dose is set low with respect to a region of a low doping concentration in the n⁻-type silicon carbide epitaxial layer 2, whereby the distribution of the concentration of the n⁻-type silicon carbide epitaxial layer 2 may be improved. In an instance of p-type Al ion-implantation, the mass is greater than that of n-type N ion-implantation and thus, damage may be increased in the crystal structure of the n⁻-type silicon carbide epitaxial layer 2 and hole injection to the drift layer may be suppressed by crystal defects generated by the damage.

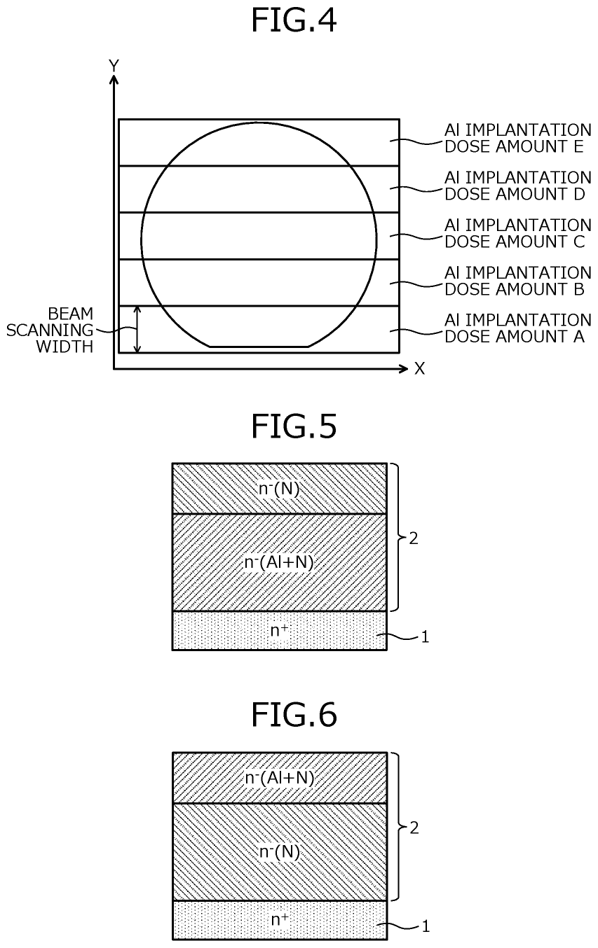

In FIGS. 2 and 3, while the region is divided into two regions including a region with a low doping concentration and a region with a high doping concentration, the region may be further divided into more regions. FIG. 4 is a top view depicting an ion implantation method of the silicon carbide semiconductor substrate according to the embodiment. FIG. 4 depicts an instance in which variation of the doping concentration is small in the x-axis direction while the variation of the doping concentration is large in the y-axis direction. Here, for each beam scanning width of ion implantation, the distribution of the carrier concentration is obtained by CV measurement, and regions are separated into regions with a low doping concentration (first regions) and regions with a high doping concentration (second regions).

In FIG. 4, as for the direction in which the variation of the doping concentration increases (the y-axis direction), the Al ion implantation dose is changed for each beam scanning width while the ion implantation is performed. For example, the minimum value of the distribution of the dopant may be examined, and the ion implantation dose for each y-axis position may be determined so as to be aligned with that value. Further, the ion implantation dose may be determined so as to be aligned with a value lower than the minimum value to induce ion implantation damage at all points. Here, the y-axis direction is the direction in which scanning and ion-implantation are performed by a mechanical scanning method. On the other hand, the x-axis direction in which the variation of the doping concentration is small is efficient when the implantation dose is fixed and scanning is by a beam scanning method.

FIGS. 5 and 6 are cross-sectional views of other structures of the silicon carbide semiconductor substrate according to the embodiment. As depicted in FIG. 5, from an interface between the n⁻-type silicon carbide epitaxial layer 2 and the n⁺-type silicon carbide substrate 1, Al ion implantation may be performed in only a predetermined region (one region having a first thickness). Further, as depicted in FIG. 6, the n⁻-type silicon carbide epitaxial layer 2 has a first surface and a second surface opposite to the first surface and facing the n⁺-type silicon carbide substrate 1, and the Al ion implantation may be performed to only a 3.3 μm portion at the first surface (another region having a second thickness) of the n⁻-type silicon carbide epitaxial layer 2. As described, even when only a portion of the depth of the drift layer is employed, a certain improvement effect may be obtained.

For example, in an instance in which the n⁻-type silicon carbide epitaxial layer 2 of the embodiment is applied to the drift layer of a MOSFET with a 1.2 kV class breakdown voltage, the Al ion-implantation to the depth of 3.3 μm and epitaxial growth may be performed multiple times, for example, three times. In other words, the n⁻-type silicon carbide epitaxial layer 2 may be formed having multiple layers, for example, three layers.

Further, the n⁻-type silicon carbide epitaxial layer 2 may be doped with a p-type dopant, for example, Al and formed by epitaxial growth, and then, may be ion-implanted with an n-type dopant, for example, N and inverted to an n-type. In an instance of deep ion implantation by a high acceleration energy, N has an ion implantation range that is deep as compared to Al and thus, is preferable.

In the conventional n⁻-type silicon carbide epitaxial layer in FIG. 16, while the carrier concentration increases with increasing distance from the center of the n⁺-type silicon carbide substrate, in the n⁻-type silicon carbide epitaxial layer 2 of the embodiment, there is no concentration difference in the net carrier concentration and variation of the carrier concentration may be expected to be small. In other words, distribution of the carrier concentration is compensated by Ntg=N0(Y)−Nadd(Y). Here, “Ntg” is assumed to be a target carrier concentration, “NO(Y)” is assumed to be distribution of the N concentration before compensation (FIG. 16), and “Nadd(Y)” is assumed to be distribution of the Al concentration to be implanted. Assuming Ntg=8.0×10¹⁵/cm³, then, from FIG. 16, when Y=−37.5 mm, then, N0=9.8×10¹⁵/cm³ and thus, Nadd=1.8×10¹⁵/cm³ suffices to be set. Further, when Y=0 mm, then, N0=8.5×10¹⁵/cm³ and thus, Nadd=0.5×10¹⁵/cm³ suffices to be set. Other Y positions are similarly compensated. In the present description, added impurities are all activated and closely resemble that acting as carriers.

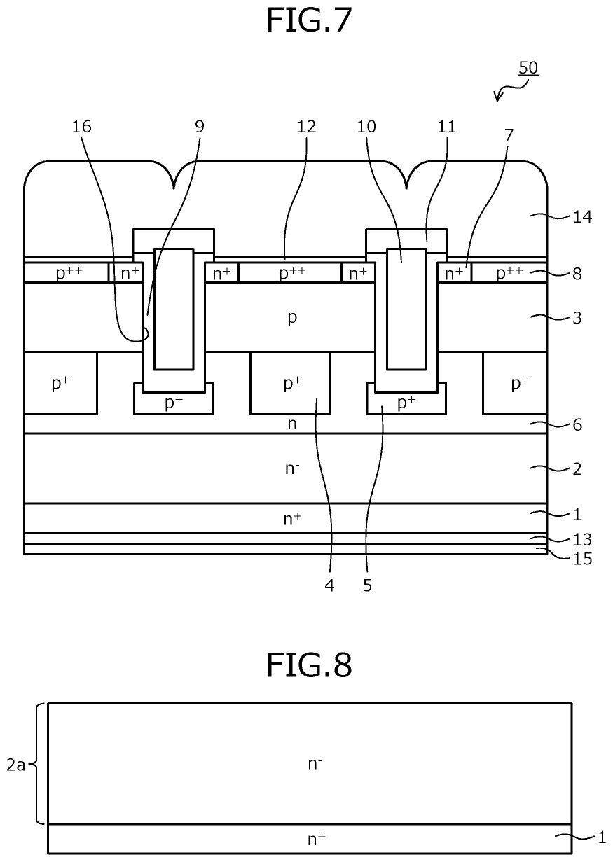

A semiconductor device according to an embodiment of the present invention is configured using a wide bandgap semiconductor. In the embodiment, a silicon carbide semiconductor device fabricated using, for example, silicon carbide (SiC), as the wide bandgap semiconductor is described taking a MOSFET as an example. FIG. 7 is cross-sectional view depicting a structure of a silicon carbide semiconductor device according to the embodiment. FIG. 7 depicts an example of a trench-type MOSFET 50.

As depicted in FIG. 7, in the silicon carbide semiconductor device according to the embodiment, at a first main surface (front surface), for example, a (0001) plane (Si-face) of the n⁺-type silicon carbide substrate (semiconductor substrate of the first conductivity type) 1, the n⁻-type silicon carbide epitaxial layer (first semiconductor layer of the first conductivity type) 2 is deposited.

The n⁺-type silicon carbide substrate 1 is a monocrystalline silicon carbide substrate. The n⁻-type silicon carbide epitaxial layer 2 is, for example, a low-concentration n-type drift layer having a doping concentration lower than that of the n⁺-type silicon carbide substrate 1. Here, the n⁻-type silicon carbide epitaxial layer 2 is fabricated by the method of manufacturing the silicon carbide semiconductor substrate according to the embodiment; variation of the distribution of the net carrier concentration of the n⁻-type silicon carbide epitaxial layer 2 is compensated and improved by ion implantation of a dopant of the conductivity type opposite to that of the n⁻-type silicon carbide epitaxial layer 2.

At the first surface of the n⁻-type silicon carbide epitaxial layer 2 opposite to the second surface thereof facing the n⁺-type silicon carbide substrate 1, an n-type high-concentration region 6 may be provided. The n-type high-concentration region 6 is a high-concentration n-type drift layer having a doping concentration lower than that of the n⁺-type silicon carbide substrate 1 and higher than that of the n⁻-type silicon carbide epitaxial layer 2.

At a first surface of the n-type high-concentration region 6, opposite to a second surface thereof facing the n⁺-type silicon carbide substrate 1 (in an instance in which the n-type high-concentration region 6 is omitted, the n⁻-type silicon carbide epitaxial layer 2, hereinafter, simply “(2)”), a p-type layer (second semiconductor layer of a second conductivity type) 3 is provided. Hereinafter, the n⁺-type silicon carbide substrate 1, the n⁻-type silicon carbide epitaxial layer 2, and the p-type layer 3 combined are assumed to be a silicon carbide semiconductor base.

At a second main surface (a back surface, i.e., a back surface of the silicon carbide semiconductor base) of the n⁺-type silicon carbide substrate 1, a drain electrode constituting a back electrode 13 is provided. At a surface of the drain electrode 13, a drain electrode pad 15 is provided.

In the silicon carbide semiconductor base, at a first main surface (surface having the p-type layer 3) thereof, a trench structure is formed. In particular, trenches 16 penetrates through the p-type layer 3 from a first surface (the first main surface of the silicon carbide semiconductor base) of the p-type layer 3, opposite to a second surface thereof facing the n⁺-type silicon carbide substrate 1 and reach the n-type high-concentration region 6 (2). Further, the trenches 16 are provided in a striped pattern. Along inner walls of the trenches 16, a gate insulating film 9 is formed on bottoms and sidewalls of the trenches 16, and gate electrodes 10 are formed on the gate insulating film 9 in the trenches 16. The gate insulating film 9 insulates the gate electrodes 10 from the n-type high-concentration region 6 (2) and the p-type layer 3. A portion of each of the gate electrodes 10 may protrude from a top (side facing a later-described source electrode pad 14) of the trenches 16 in a direction to the source electrode pad 14.

In a surface layer of the n-type high-concentration region 6 (2), at the first surface thereof (the first main surface of the silicon carbide semiconductor base) opposite to the second surface thereof facing the n⁺-type silicon carbide substrate 1, first p⁺-type base regions 4 are selectively provided. The first p⁺-type base regions 4 are apart from the trenches 16 and reach deep positions closer to a drain than are the bottoms of the trenches 16.

At positions facing the bottoms of the trenches 16 in the depth direction, second p⁺-type base regions 5 are provided. A width of each of the second p⁺-type base regions 5 may be equal to or wider than a width of each of the trenches 16. The bottoms of the trenches 16 may reach the second p⁺-type base regions 5 or may be positioned in the n-type high-concentration region 6 (2), sandwiched between the p-type layer 3 and the second p⁺-type base regions 5. The first p⁺-type base regions 4 and the second p⁺-type base regions 5 are doped with, for example, aluminum (Al). The structure may be such that portions of each of the first p⁺-type base regions 4 extend toward the trenches 16 adjacent thereto to thereby be connected to the second p⁺-type base regions 5. A reason for this is that holes occurring when avalanche breakdown occurs at portions connecting the n-type high-concentration region 6 (2) and the second p⁺-type base regions 5 are efficiently migrated to a source electrode 12, whereby load on the gate insulating film 9 is decreased and reliability is increased. FIG. 7 depicts an instance in which the first p⁺-type base regions 4 and the second p⁺-type base regions 5 are disposed apart from each other.

The p-type layer 3 is in contact with the first p⁺-type base regions 4. In the p-type layer 3, at the first surface thereof, n⁺-type source regions (first semiconductor regions of the first conductivity type) 7 are provided. Further, p⁺⁺-type contact regions 8 may be selectively provided. In this instance, the n⁺-type source regions 7 and the p⁺⁺-type contact regions 8 are in contact with one another.

In a surface layer of the n⁻-type silicon carbide epitaxial layer 2, at the first surface thereof, the n-type high-concentration region 6 may be provided in regions sandwiched between the first p⁺-type base regions 4 and the second p⁺-type base regions 5 adjacent thereto and in regions sandwiched between the p-type layer 3 and the second p⁺-type base regions 5; the n-type high-concentration region 6 is formed to a position deeper than are the first p⁺-type base regions 4 and the second p⁺-type base regions 5. Thus, a depth (thickness) of the n-type high-concentration region 6 is greater than a depth (thickness) of each of the first p⁺-type base regions 4 and a depth (thickness) of each of the second p⁺-type base regions 5. Further, the first p⁺-type base regions 4 and the second p⁺-type base regions 5 may be formed to positions at a same depth. Further, the n-type high-concentration region 6 may be provided so as to surround the first p⁺-type base regions 4 and the second p⁺-type base regions 5 on a drain-side of the first p⁺-type base regions 4 and the second p⁺-type base regions 5.

In FIG. 7, while only two trench-MOS structures are depicted, further MOS gate (metal-oxide-semiconductor insulated gate) structures with the trench structure may be disposed.

At the entire first main surface of the silicon carbide semiconductor base, an interlayer insulating film 11 is provided so as to cover the gate electrodes 10 embedded in the trenches 16. The source electrode (first electrode) 12 in contact with the n⁺-type source regions 7 and the p⁺⁺-type contact regions 8 via contact holes opened in the interlayer insulating film 11 is provided. The source electrode 12 is electrically insulated from the gate electrodes 10 by the interlayer insulating film 11. On the source electrode 12, the source electrode pad 14 is provided.

Next, a method of manufacturing the silicon carbide semiconductor device according to the embodiment is described. FIGS. 8, 9, 10, 11, 12, and 13 are cross-sectional views schematically depicting states of the silicon carbide semiconductor device according to the embodiment during manufacture.

First, as depicted in FIG. 8, the n⁺-type silicon carbide substrate 1 containing an n-type silicon carbide is prepared. Subsequently, on the first main surface of the n⁺-type silicon carbide substrate 1, a first n⁻-type silicon carbide epitaxial layer 2a containing silicon carbide is epitaxially grown to have a thickness of, for example, about 30 μm while an n-type dopant, for example, nitrogen atoms, is doped. Next, the distribution of the doping concentration of the first n⁻-type silicon carbide epitaxial layer 2a is obtained by CV measurement. Here, a Hg-CV measurement may be taken using a separate silicon carbide semiconductor substrate set for an epi-deposition monitor, a Hg-CV measurement may be taken directly using a ring-dot electrode, or the carrier concentration may be measured optically, a method without contact to the surface of the substrate. Next, a p-type dopant is ion-implanted in the first n′-type silicon carbide epitaxial layer 2a. Here, in the first n⁻-type silicon carbide epitaxial layer 2a, for a region where the doping concentration is low (first region), the p-type ion implantation dose decreased while for a region where the doping concentration is high (second region), the p-type ion implantation dose is increased, whereby the distribution of the net carrier concentration of the n⁻-type silicon carbide epitaxial layer 2a may be improved. The first n⁻-type silicon carbide epitaxial layer 2a constitutes the n⁻-type silicon carbide epitaxial layer 2. The state up to here is depicted in FIG. 8.

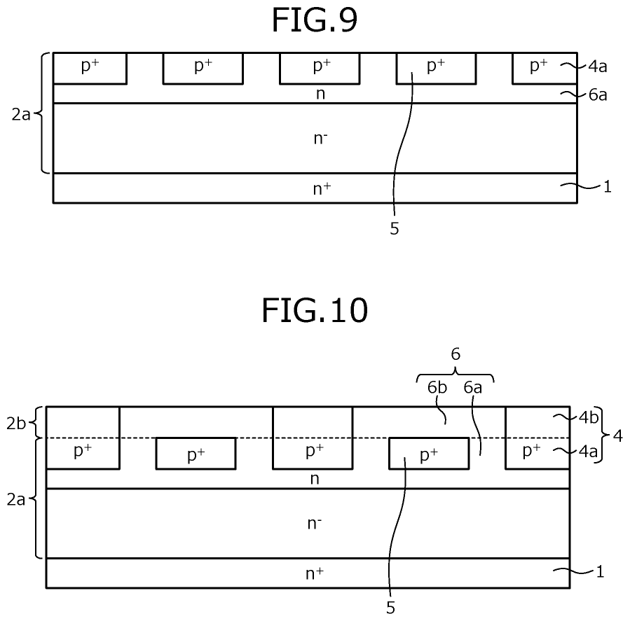

Next, as depicted in FIG. 9, on the surface of the first n⁻-type silicon carbide epitaxial layer 2a, a non-depicted mask having predetermined openings is formed by photolithography using, for example, an oxide film. Subsequently, a p-type dopant, for example, aluminum atoms, is ion-implanted by an ion implantation method using the oxide film as a mask. As a result, as depicted in FIG. 9, in the first n⁻-type silicon carbide epitaxial layer 2a, at the surface thereof, for example, the second p⁺-type base regions 5 and first p⁺-type regions 4a of a depth of about 0.5 μm are formed, for example, so as to have a distance of about 1.5 μm between any one of the first p⁺-type regions 4a and an adjacent one of the second p⁺-type base regions 5.

Next, the mask used to form the first p⁺-type regions 4a and the second p⁺-type base regions 5 is removed. Subsequently, an n-type dopant, for example, nitrogen atoms, may be ion-implanted by an ion implantation method. As a result, as depicted in FIG. 9, in a surface layer of the first n⁻-type silicon carbide epitaxial layer 2a, a first n-type region 6a is formed between the first p⁺-type regions 4a and the second p⁺-type base regions 5, to a position in a range of 0.2 to 0.5 μm deeper than are the first p⁺-type regions 4a and the second p⁺-type base regions 5. In an instance in which the n-type high-concentration region 6 is omitted, formation of the first n-type region 6a and second n-type regions 6b is omitted. Here, ion implantation for forming the first n-type region 6a is performed without using a mask, thus, the first n-type region 6a is formed so as to span the entire surface layer of the first n⁻-type silicon carbide epitaxial layer 2a and surround lower sides of the first p⁺-type regions 4a and lower sides of the second p⁺-type base regions 5 (sides facing the n⁺-type silicon carbide substrate 1). The dose during the ion-implantation for forming the first n-type region 6a, for example, may be set so that the doping concentration becomes about 5×10¹⁶/cm³. The state up to here is depicted in FIG. 9.

Next, as depicted in FIG. 10, on the surface of the first n⁻-type silicon carbide epitaxial layer 2a, a second n⁻-type silicon carbide epitaxial layer 2b is epitaxially grown having a thickness of, for example, about 0.5 μm while an n-type dopant, for example, nitrogen atoms, is doped. Next, the distribution of the dopant of the second n⁻-type silicon carbide epitaxial layer 2b is obtained by CV measurement. Here, a Hg-CV measurement may be taken using a separate silicon carbide semiconductor substrate set for an epi-deposition monitor, a Hg-CV measurement may be taken directly using a ring-dot electrode, or the carrier concentration may be measured optically, a method without contact to the surface of the substrate. Next, a p-type dopant is ion-implanted in the second n⁻-type silicon carbide epitaxial layer 2b. Here, in the second n⁻-type silicon carbide epitaxial layer 2b, for a region where the doping concentration is low, the p-type ion implantation dose is reduced while for a region where the doping concentration is high, the p-type ion implantation dose is increased, whereby the distribution of the net carrier concentration of the n⁻-type silicon carbide epitaxial layer 2b is improved. The second n⁻-type silicon carbide epitaxial layer 2b and the first n⁻-type silicon carbide epitaxial layer 2a combined constitute the n⁻-type silicon carbide epitaxial layer 2. Conditions of the epitaxial growth for forming the second n⁻-type silicon carbide epitaxial layer 2b may be set so that, for example, the doping concentration of the second n⁻-type silicon carbide epitaxial layer 2b becomes about 3×10¹⁵/cm³.

Next, on the surface of the n⁻-type silicon carbide epitaxial layer 2, a non-depicted mask having predetermined openings is formed by photolithography using, for example, an oxide film. Subsequently, a p-type dopant, for example, aluminum atoms, is ion-implanted by an ion implantation method using the oxide film as a mask. As a result, as depicted in FIG. 10, in the n⁻-type silicon carbide epitaxial layer 2, at the surface thereof, second p⁺-type regions 4b of a depth of for example, about 0.5 μm are formed so as to overlap, for example, upper portions of the first p⁺-type regions 4a. The second p⁺-type regions 4b and the first p⁺-type regions 4a combined constitute the first p⁺-type base regions 4.

Next, the mask used during the ion implantation for forming the second p⁺-type regions 4b is removed. Subsequently, an n-type dopant, for example, nitrogen atoms, is ion-implanted by an ion implantation method. As a result, as depicted in FIG. 10, in a surface layer of the second n⁻-type silicon carbide epitaxial layer 2b, for example, the second n-type regions 6b of a depth of about 0.5 μm are formed so as to be in contact with the first p⁺-type base regions 4, the second p⁺-type base regions 5, and the first n-type region 6a. The dose during the ion implantation for forming the second n-type regions 6b, for example, may be set so that the doping concentration becomes about 5×10¹⁶/cm³. The second n-type regions 6b and the first n-type region 6a combined constitute the n-type high-concentration region 6. The state up to here is depicted in FIG. 10.

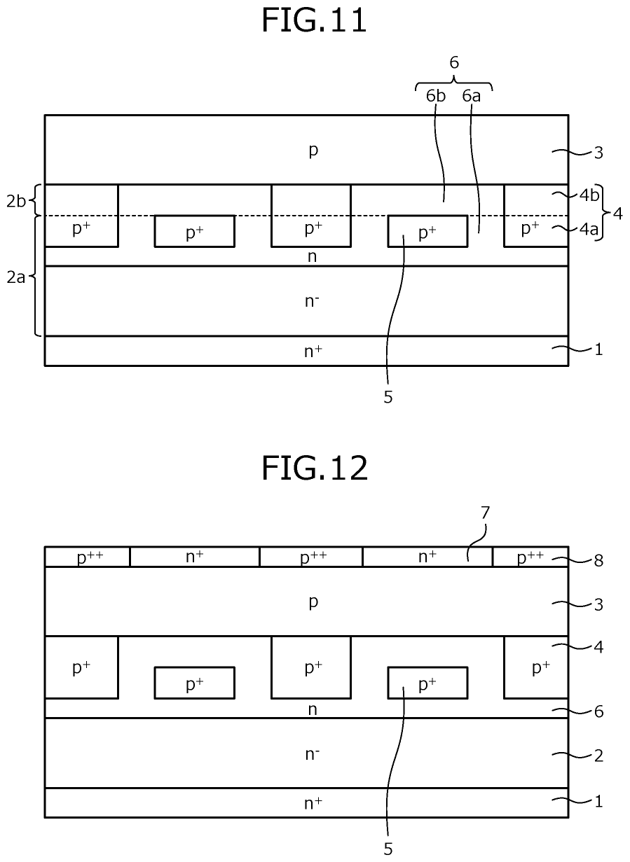

Next, as depicted in FIG. 11, on the surface of the n⁻-type silicon carbide epitaxial layer 2 (i.e., surfaces of the first p⁺-type base regions 4 and surfaces of the second n-type regions 6b), the p-type layer 3 is epitaxially growing having a thickness of, for example, about 1.3 μm while a p-type dopant, for example, aluminum atoms, is doped. Conditions of the epitaxial growth for forming the p-type layer 3, for example, may be set so that doping concentration is lower than the doping concentration of the first p⁺-type base regions 4 and becomes about 4×10¹⁷/cm³. By the processes up to here, the silicon carbide semiconductor base in which the n⁻-type silicon carbide epitaxial layer 2 and the p-type layer 3 are stacked on the n⁺-type silicon carbide substrate 1 is formed. The state up to here is depicted in FIG. 11.

Next, on the surface of the p-type layer 3, a non-depicted mask having predetermined openings is formed by photolithography using, for example, an oxide mask. Subsequently, an n-type dopant, for example, phosphorus (P) is ion-implanted by an ion implantation method using the oxide film as a mask. As a result, as depicted in FIG. 12, in the p-type layer 3, at the surface thereof, the n⁺-type source regions 7 are formed. Here, a width of each of the n⁺-type source regions 7 is formed so as to be narrower than a width of each of the p⁺⁺-type contact regions 8. The dose during the ion implantation for forming the n⁺-type source regions 7, for example, is set so that the doping concentration becomes higher than that of the first p-type base regions 4.

Next, the mask used during the ion implantation for forming the n⁺-type source regions 7 is removed. Subsequently, on the exposed surface of the p-type layer 3, a non-depicted mask having predetermined openings is formed by photolithography using, for example, an oxide film and a p-type dopant, for example, aluminum, is ion-implanted into the surface of the p-type layer 3, using the oxide film as a mask. As a result, in the p-type layer 3, at the surface thereof, the p⁺⁺-type contact regions 8 are formed. The dose during the ion implantation for forming the p⁺⁺-type contact regions 8, for example, may be set so that the dopant concentration becomes higher than that of the second p⁺-type base regions 5. A sequence in which the ion implantation for forming the n⁺-type source regions 7 and the ion implantation for forming the p⁺⁺-type contact regions 8 may be interchanged. The state up to here is depicted in FIG. 12.

Next, a heat treatment (annealing) is performed, activating, for example, the first p⁺-type regions 4a, the second p⁺-type regions 4b, the n⁺-type source regions 7, and the p⁺⁺-type contact regions 8. A temperature of the heat treatment may be, for example, about 1700 degrees C. A period of the heat treatment may be, for example, about two minutes. As described above, ion-implanted regions may be collectively activated by a single session of the heat treatment or may be activated by performing the heat treatment each time ion implantation is performed.

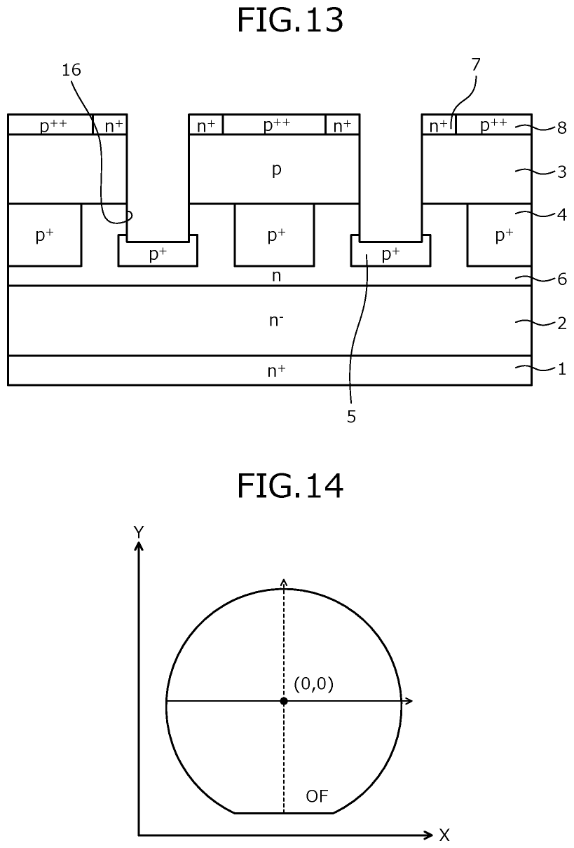

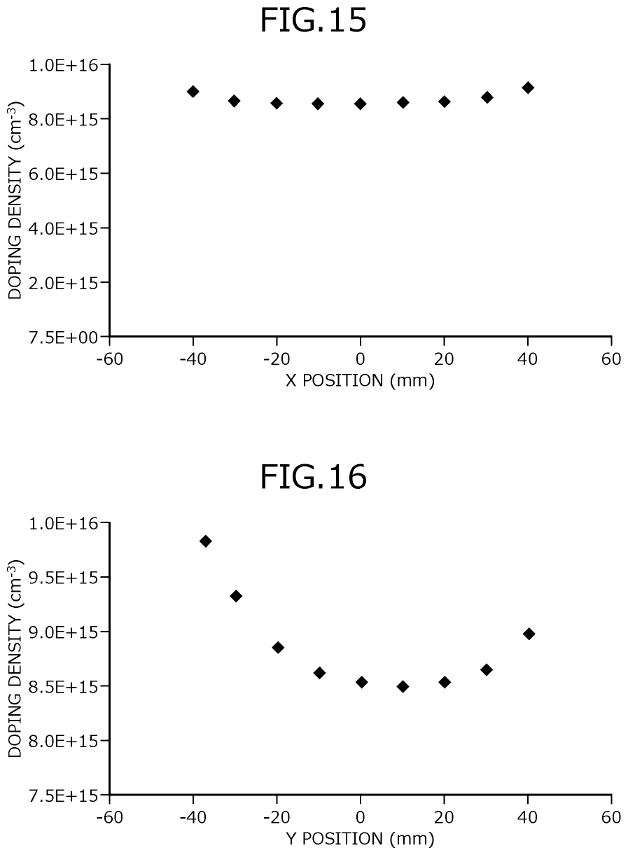

Next, as depicted in FIG. 13, on the surface of the p-type layer 3 (i.e., surfaces of the n⁺-type source regions 7 and surfaces of the p⁺⁺-type contact regions 8), a non-depicted mask having predetermined openings is formed by photolithography using, for example, an oxide film. Subsequently, the trenches 16 that penetrate through the n⁺-type source regions 7 and reach the n-type high-concentration region 6 (in an instance in which the n-type high-concentration region 6 is omitted, the n⁻-type silicon carbide epitaxial layer 2) are formed by etching or the like using the oxide film as a mask. The bottoms of the trenches 16 may reach the second p⁺-type base regions 5 or may be positioned in the n-type high-concentration region 5 (in an instance in which the n-type high-concentration region 6 is omitted, the n⁻-type silicon carbide epitaxial layer 2), sandwiched between the p-type layer 3 and the second p⁺-type base regions 5. Next, the mask used for forming the trenches 16 is removed. The state up to here is depicted in FIG. 13.

Next, along the surfaces of the n⁺-type source regions 7 and the surfaces of the p⁺⁺-type contact regions 8 as well as along the bottoms and sidewalls of the trenches 16, the gate insulating film 9 is formed. The gate insulating film 9 may be formed by thermal oxidation by a heat treatment of about 1000 degrees C. in an oxygen atmosphere. Further, the gate insulating film 9 may be formed by a deposition method by a chemical reaction such as that for a high temperature oxide (HTO).

Next, on the gate insulating film 9, a polycrystalline silicon layer doped with, for example, phosphorus atoms, is formed. The polycrystalline silicon layer is formed so as to be embedded in the trenches 16. The polycrystalline silicon layer is patterned and left in the trenches 16, whereby the gate electrodes 10 are formed. A portion of each of the gate electrodes 10 may protrude from a top (side facing the source electrode pad 14) of the trench 16 in a direction to the source electrode pad 14.

Next, for example, a phosphate glass is deposited so as to cover the gate insulating film 9 and the gate electrodes 10 and have a thickness of about 1 μm, whereby the interlayer insulating film 11 is formed. The interlayer insulating film 11 and the gate insulating film 9 are patterned and selectively removed, thereby, forming contact holes and exposing the n⁺-type source regions 7 and the p⁺⁺-type contact regions 8. Thereafter, a heat treatment (reflow) is performed, thereby planarizing the interlayer insulating film 11.

Next, for example, by a sputtering method, the source electrode 12 that is in contact with the n⁺-type source regions 7 and the p⁺⁺-type contact regions 8 is formed. Next, for example, by a sputtering method, for example, an aluminum film with a thickness of, for example, about 5 μm is formed so as to cover the source electrode 12 and the interlayer insulating film 11. Thereafter, the aluminum is selectively removed so that a portion is left covering the entire active region of the device, thereby, forming the source electrode pad 14.

Next, for example, by a sputtering method, at the second main surface of the n⁺-type silicon carbide substrate 1, the drain electrode 13 is formed. Next, on the surface of the drain electrode 13, for example, titanium (Ti), nickel (Ni), and gold (Au) are sequentially deposited, thereby forming the drain electrode pad 15. As described, the semiconductor device depicted in FIG. 7 is completed.

As described, according to the embodiment, in the n⁻-type silicon carbide epitaxial layer, for a region thereof where the doping concentration is low, the dose is reduced and in the n⁻-type silicon carbide epitaxial layer, for a region thereof where the doping concentration is high, the dose is increased, p-type ion implantation is performed, and thus the distribution of the net carrier concentration of the n⁻-type silicon carbide epitaxial layer 2b is improved. As a result, variation of the breakdown voltage and variation of the on-resistance of the MOSFET may be improved. Further, hole injection to the drift layer may be suppressed by crystal defects generated by the ion implantation, whereby expansion of stacking faults may be suppressed even when a body diode conducts.

In the foregoing, the present invention may be variously modified within a range not departing from the spirit of the invention and in the embodiments described above, for example, dimensions, doping concentrations, etc. of regions, etc. are variously set according to necessary specifications. Further, in the embodiments, while the first conductivity type is assumed to be a p-type and the second conductivity type is assumed to be an n-type, the present invention is similarly implemented when the first conductivity type is an n-type and the second conductivity type is a p-type.

### INDUSTRIAL APPLICABILITY

As described, the silicon carbide semiconductor device and the method of manufacturing the silicon carbide semiconductor device are useful for power semiconductor devices used in power converting equipment such as inverters, power source devices of various industrial machines, etc.

### EXPLANATIONS OF LETTERS OR NUMERALS

1 n⁺-type silicon carbide substrate
2 n⁻-type silicon carbide epitaxial layer
2a first n⁻-type silicon carbide epitaxial layer
2b second n⁻-type silicon carbide epitaxial layer
3 p-type base layer
4 first p⁺-type base region
4a first p⁺-type region
4b second p⁺-type region
5 second p⁺-type base region
6 n-type high-concentration region
6a first n-type region
6b second n-type region
7 n⁺-type source region
8 p⁺⁺-type contact region
9 gate insulating film
10 gate electrode
11 interlayer insulating film
12 source electrode
13 back electrode
14 source electrode pad
15 drain electrode pad
16 trench
21 n-type silicon carbide epitaxial layer low-concentration region
22 r-type silicon carbide epitaxial layer high-concentration region
50 trench-type MOSFET
60 silicon carbide semiconductor substrate

1. A silicon carbide semiconductor substrate, comprising:
a silicon carbide semiconductor substrate of a first conductivity type, having a first main surface and a second main surface opposite to each other; and
a first semiconductor layer of the first conductivity type, provided at the first main surface of the silicon carbide semiconductor substrate, and having a doping concentration lower than a doping concentration of the silicon carbide semiconductor substrate, wherein a portion of the first semiconductor layer contains a dopant of a second conductivity type, and
a concentration of the dopant of the second conductivity type in the first semiconductor layer differs in a direction parallel to an orientation flat or in a direction orthogonal to the orientation flat, the orientation flat indicating a crystal axis direction, such that a distribution of a net carrier concentration in the first semiconductor layer has a variation equal to or less than a predetermined threshold.

2. A method of manufacturing a silicon carbide semiconductor substrate, the method comprising:
forming a first semiconductor layer of a first conductivity type, at a first main surface of a silicon carbide semiconductor substrate of the first conductivity type, the first semiconductor layer having a doping concentration lower than a doping concentration of the silicon carbide semiconductor substrate, the first semiconductor layer including a first region and a second region, the doping concentration being lower in the first region than in the second region;
measuring a distribution of the doping concentration of the first semiconductor layer, thereby detecting the first region and the second region; and
implanting a dopant of a second conductivity type in the first semiconductor layer, wherein
the implanting the dopant includes reducing an implantation amount of the dopant of the second conductivity type for the first region and increasing the implantation amount of the dopant of the second conductivity type for the second region, such that a distribution of a net carrier concentration in the first semiconductor layer has a variation equal to or less than a predetermined threshold.

3. The method according to claim 2, wherein
the implanting the dopant includes implanting the dopant of the second conductivity type in a region from an interface between the silicon carbide semiconductor substrate and the first semiconductor layer.

4. The method according to claim 2, wherein
the first semiconductor layer has a first surface and a second surface opposite to each other, the second surface facing the silicon carbide semiconductor substrate, and
the implanting the dopant includes implanting the dopant of the second conductivity type in a region of the first semiconductor layer, at the first surface thereof.

5. A silicon carbide semiconductor device, comprising:
a silicon carbide semiconductor substrate of a first conductivity type, having a first main surface and a second main surface opposite to each other;
a first semiconductor layer of the first conductivity type, provided at the first main surface of the silicon carbide semiconductor substrate and having a doping concentration lower than a doping concentration of the silicon carbide semiconductor substrate, the first semiconductor layer having a first surface and a second surface opposite to each other, the second surface facing the silicon carbide semiconductor substrate;
a second semiconductor layer of a second conductivity type, provided at the first surface of the first semiconductor layer and having a first surface and a second surface opposite to each other, the second surface of the second semiconductor layer facing the silicon carbide semiconductor substrate;
a first semiconductor region of the first conductivity type, selectively provided in the second semiconductor layer, at the first surface of the second semiconductor layer;
a trench penetrating through the second semiconductor layer and the first semiconductor region and reaching the first semiconductor layer;
a gate electrode provided on a gate insulating film in the trench;
a first electrode in contact with the first semiconductor region and the second semiconductor layer; and
a second electrode provided at the second main surface of the silicon carbide semiconductor substrate, wherein
a portion of the first semiconductor layer contains a dopant of the second conductivity type,
a concentration of the dopant of the second conductivity type in the first semiconductor layer differs in a direction parallel to an orientation flat or in a direction orthogonal to the orientation flat, the orientation flat indicating a crystal axis direction, such that a distribution of a net carrier concentration in the first semiconductor layer has a variation equal to or less than a predetermined threshold.

6. A method of manufacturing a silicon carbide semiconductor device, the method comprising:
forming a first semiconductor layer of a first conductivity type, at a first main surface of a silicon carbide semiconductor substrate of the first conductivity type, the first semiconductor layer having a doping concentration lower than a doping concentration of the silicon carbide semiconductor substrate, the first semiconductor layer having a first surface and a second surface opposite to each other, the second surface facing the silicon carbide semiconductor substrate, the first semiconductor layer including a first region and a second region, the doping concentration being lower in the first region than in the second region;
measuring a distribution of the doping concentration of the first semiconductor layer, thereby detecting the first region and the second region;
implanting a dopant of a second conductivity type in the first semiconductor layer;
forming a second semiconductor layer of the second conductivity type at the first surface of the first semiconductor layer;
selectively forming a first semiconductor region of the first conductivity type at a surface of the second semiconductor layer;
forming a trench that penetrates through the second semiconductor layer and the first semiconductor region and reaches the first semiconductor layer;
forming a gate electrode in the trench via a gate insulating film;
forming a first electrode in contact with the first semiconductor region and the second semiconductor layer; and
forming a second electrode at the second main surface of the silicon carbide semiconductor substrate, wherein
the implanting the dopant includes reducing an implantation amount of the dopant of the second conductivity type for the first region and increasing the implantation amount of the dopant of the second conductivity type for the second region, such that a distribution of a net carrier concentration in the first semiconductor layer has a variation equal to or less than a predetermined threshold.
